(19) United States
(12) Patent Application Publication
(10) Pub. No.: US 2026/0188253 A1
(43) Pub. Date: Jul. 2, 2026

(54) Gate Driving Circuit and Display Device Including the Same

(71) Applicant: LG Display Co., Ltd., Seoul (KR)

(72) Inventors: Minwoo Park, Paju-si (KR); Junho Bong, Paju-si (KR); YeonGyeong Bae, Paju-si (KR)

(21) Appl. No.: 19/410,995

(22) Filed: Dec. 5, 2025

(30) Foreign Application Priority Data
Dec. 30, 2024 (KR) 10-2024-0200123

(51) Int. Cl. G09G 3/3266; G09G 3/3233; G09G 3/36

(52) U.S. Cl. CPC G09G 3/3266; G09G 3/3233; G09G 3/3677; G09G 2300/0408; G09G 2300/0426; G09G 2300/0819; G09G 2300/0842; G09G 2300/0861; G09G 2310/08; G09G 2320/0223; G09G 2330/021

(57) ABSTRACT

A display device presented herein comprises a display area, a non-display area, and a gate driving circuit outputting a gate signal to the display area. The gate driving circuit includes a first transistor controlling a connection between a first node and a second node to which a start signal is input according to a first clock signal, a second transistor controlling a connection between the first node and a control node according to the first clock signal, a third transistor controlling a connection between the second node and the control node according to a second clock signal, a fourth transistor controlling a connection between the first node and a third node to which a high level gate voltage is input according to the first clock signal, and an output circuit outputting the gate signal to the display area according to a voltage level of the control node.

### CROSS-REFERENCE TO RELATED APPLICATION

The present application claims priority to Republic of Korea Patent Application No. 10-2024-0200123, filed on December 30, 2024, which is hereby incorporated by reference in its entirety.

### BACKGROUND

### Field

The present disclosure relates to a gate driving circuit and a display device including the same.

### Discussion of Related Art

As the information society develops, demand for display devices for displaying images is increasing in various forms. Various types of display devices, such as liquid crystal display devices and organic light emitting display devices, are being utilized in recent years.

The description provided in the description of the related art section should not be assumed to be prior art merely because it is mentioned in or associated with the description of the related art section. The description of the related art section may include information that describes one or more embodiments of the subject technology, and the description in this section does not limit the present disclosure.

### SUMMARY

The inventor has realized that a limitation exists in transistors of the gate driving circuits in related art. Accordingly, embodiments of the present disclosure may provide a gate driving circuit including a transistor for preventing unintended current flow and a display device including the same.

Embodiments of the present disclosure may provide a gate driving circuit including a transistor that forms a gate-source voltage lower than the threshold voltage by receiving a high level gate voltage through the source node and a display device including the same.

Objects of embodiments of the present disclosure are not limited to those set forth herein, and other unmentioned objects would be apparent to one of ordinary skill in the art from the following description.

Embodiments of the present disclosure may provide a display device comprising a display area where an image is displayed, a non-display area partitioning an outside of the display area, and a gate driving circuit outputting a gate signal to the display area, wherein the gate driving circuit includes a first transistor controlling a connection between a first node and a second node to which a start signal is input according to a first clock signal input to a first gate node, a second transistor controlling a connection between the first node and a control node according to the first clock signal input to a second gate node, a third transistor controlling a connection between the second node and the control node according to a second clock signal input to a third gate node, a fourth transistor controlling a connection between the first node and a third node to which a high level gate voltage is input according to the first clock signal input to a fourth gate node, and an output circuit outputting the gate signal to the display area according to a voltage level of the control node.

Embodiments of the present disclosure may provide a gate driving circuit comprising a first transistor controlling a connection between a first node and a second node to which a start signal is input according to a first clock signal input to a first gate node, a second transistor controlling a connection between the first node and a control node according to the first clock signal input to a second gate node, a third transistor controlling a connection between the second node and the control node according to a second clock signal input to a third gate node, a fourth transistor controlling a connection between the first node and a third node to which a high level gate voltage is input according to the first clock signal input to a fourth gate node, and an output circuit outputting a gate signal to an output node according to a voltage level of the control node.

Embodiments of the present disclosure may provide a display device including a plurality of subpixels, each subpixel comprising: a driving transistor having a first electrode, a second electrode and a gate electrode; a first scan transistor that is controlled by a first scan signal and is electrically connected between the first electrode and the gate electrode of the driving transistor; a second scan transistor that is controlled by a second scan signal and is electrically connected to a data line, and the second electrode of the driving transistor; a first emission control transistor that is controlled by a first emission control signal and is electrically connected between a driving voltage line and the first electrode of the driving transistor; a second emission control transistor that is controlled by a second emission control signal, and is electrically connected between the second electrode of the driving transistor and a anode electrode of a light emitting element; a third emission control transistor that is controlled by the second emission control signal, and is connected between an initialization voltage line and the anode electrode of the light emitting element; and a capacitor that is electrically connected between the gate electrode of the driving transistor and the anode electrode of the light emitting element.

According to embodiments of the present disclosure, there may be provided a gate driving circuit that maintains the voltage of the control node while a start signal has a low level voltage and is not input to the control node and a display device including the same.

According to embodiments of the present disclosure, there may be provided a gate driving circuit that is driven at low power by preventing a voltage drop at the control node which controls the gate signal and a display device including the same.

The effects of the present disclosure are not limited to the foregoing objects, and other effects will be apparent to one of ordinary skill in the art from the following detailed description.

### BRIEF DESCRIPTION OF THE DRAWINGS

The present disclosure will be more fully understood from the following detailed description and the accompanying drawings, which are provided for illustration only and are not intended to limit the present disclosure.

FIG. 1 is a system view illustrating a display device according to one or more embodiments of the present disclosure.

FIG. 2 is a plan view illustrating a display device according to one or more embodiments of the present disclosure.

FIG. 3 is a cross-sectional view illustrating a display device according to one or more embodiments of the present disclosure.

FIG. 4 is an example view illustrating a subpixel according to one or more embodiments of the present disclosure.

FIG. 5 is a view illustrating a connection relationship between a gate driving integrated circuit and a display area according to one or more embodiments of the present disclosure.

FIG. 6 is an example view illustrating an emission control driver according to one or more embodiments of the present disclosure.

FIG. 7 is a timing diagram illustrating an emission control driver according to one or more embodiments of the present disclosure.

FIG. 8 is a view illustrating a first driving period of an emission control driver according to one or more embodiments of the present disclosure.

FIG. 9 is a view illustrating a second driving period of an emission control driver according to one or more embodiments of the present disclosure.

FIG. 10 is a view illustrating a third driving period of an emission control driver according to one or more embodiments of the present disclosure.

FIG. 11 is a view illustrating a fourth driving period of an emission control driver according to one or more embodiments of the present disclosure.

FIG. 12 is a view illustrating a fifth driving period of an emission control driver according to one or more embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the present disclosure and may be thus different from those used in actual products.

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “include,” “have,” “comprise,” “contain,” “constitute,” “make up of,” “formed of,” and “consist of” used herein are generally intended to allow other components to be added unless the terms are used with the term “only”. As used herein, singular forms are intended to include plural forms unless the context clearly indicates otherwise.

The shapes, sizes, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the present disclosure.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

When the position relation between two parts is described using the terms such as “on”, “above”, “over”, “below”, “under”, “beside”, “beneath”, “near”, “close to,” “adjacent to”, “on a side of”, “next”, one or more parts may be positioned between the two parts unless the terms are used with the term “immediately” or “directly”.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element may be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

The term "at least one" should be understood as including all possible combinations which can be suggested from one or more relevant items. For example, the meaning of "at least one of a first item, a second item, or a third item" may be each one of the first item, the second item, or the third item and also be all possible combinations that can be suggested from two or more of the first item, the second item, and the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

The word“exemplary”is used to mean serving as an example or illustration. Aspects are example aspects. “Embodiments,”“examples,”“aspects,” and the like should not be construed as preferred or advantageous over other implementations. An embodiment, an example, an exemplary embodiment, an aspect, or the like may refer to one or more embodiments, one or more examples, one or more example embodiments, one or more aspects, or the like, unless stated otherwise.

Unless otherwise defined, all terms (including technical and scientific terms) used herein have the same meaning as commonly understood by one of ordinary skill in the art to which embodiments of the present disclosure belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In embodiments of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In the present disclosure, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

Hereinafter, various embodiments of the present disclosure are described in detail with reference to the accompanying drawings.

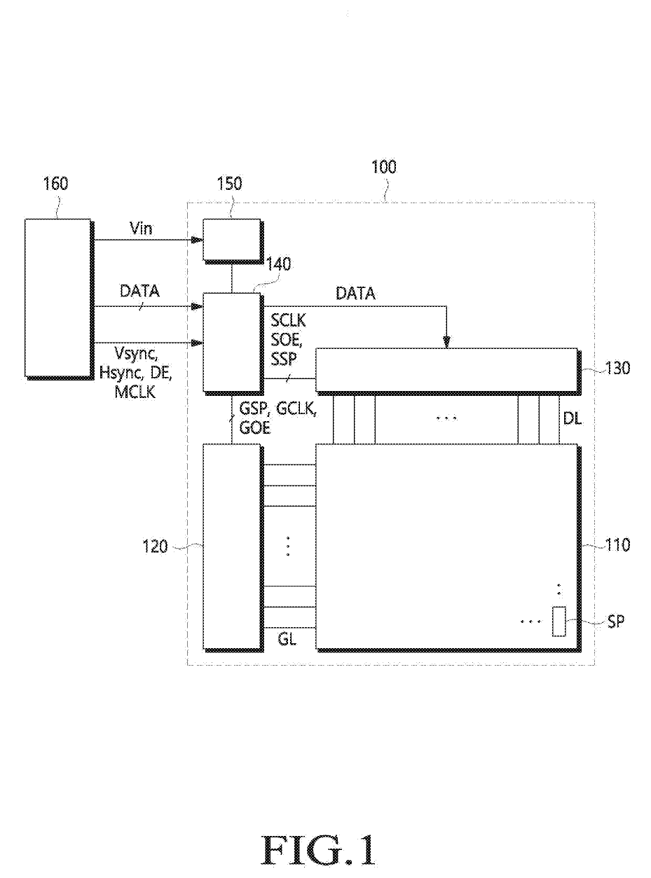

FIG. 1 is a system view illustrating a display device 100 according to one or more embodiments of the present disclosure.

Referring to FIG. 1, a display device 100 according to one or more embodiments of the present disclosure may include a display panel 110 where a plurality of gate lines GL and data lines DL are connected, and a plurality of subpixels SP are arranged in a matrix form, a gate driving circuit 120 driving the plurality of gate lines GL, a data driving circuit 130 supplying a data voltage through the plurality of data lines DL, a controller 140 controlling the gate driving circuit 120 and the data driving circuit 130, and a power management circuit 150.

The display panel 110 displays an image based on a scan signal and an emission control signal transferred from the gate driving circuit 120 through the plurality of gate line GL and the data voltage transferred from the data driving circuit 130 through the plurality of data lines DL.

In the case of a liquid crystal display, the display panel 110 may include a liquid crystal layer formed between two substrates and may be operated in any known mode, such as a twisted nematic (TN) mode, a vertical alignment (VA) mode, an in-plane switching (IPS) mode, or a fringe field switching (FFS) mode. In the case of an organic light emitting display, the display panel 110 may be implemented in a top emission scheme, a bottom emission scheme, or a dual-emission scheme. However, the present disclosure is not limited thereto.

In the display panel 110, a plurality of pixels may be arranged in a matrix form, and each pixel may include subpixels SP having different colors, e.g., a white subpixel, a red subpixel, a green subpixel, and a blue subpixel, and each subpixel SP may be defined by the plurality of data lines DL and the plurality of gate lines GL. Meanwhile, the sub-pixels may also include white sub-pixel. The plurality of subpixels may be variously modified in colors and configurations, as necessary. However, the present disclosure is not limited thereto.

For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in one or more embodiments of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

One subpixel SP may include, e.g., a thin film transistor (TFT) formed at the intersection between one data line DL and one gate line GL, a light emitting element, such as an organic light emitting diode, charged with the data voltage, and a storage capacitor electrically connected to the light emitting element to maintain the voltage.

For example, when the display device 100 having a resolution of 2,160 X 3,840 includes four subpixels SP of white (W), red (R), green (G), and blue (B), 3,840 data lines DL may be connected to 2,160 gate lines GL and four subpixels WRGB, and thus, there may be provided 3,840 X 4 = 15,360 data lines DL. Each subpixel SP is disposed at the intersection between the gate line GL and the data line DL.

The gate driving circuit 120 may be controlled by the controller 140 to sequentially output scan signals to the plurality of gate lines GL disposed in the display panel 110, thereby controlling the driving timing of the plurality of subpixels SP.

In the display device 100 having a resolution of 2,160 X 3,840, sequentially outputting the scan signal to the 2,160 gate lines GL from the first gate line to the 2160th gate line may be referred to as 2,160-phase driving. Sequentially outputting the scan signal to each unit of four gate lines GL, e.g., sequentially outputting the scan signal to the fifth gate line to the eighth gate line after sequentially outputting the scan signal to the first gate line to the fourth gate line, is referred to as 4-phase driving. In other words, sequentially outputting the scan signal to every N gate lines GL may be referred to as N-phase driving.

The gate driving circuit 120 may include one or more gate driving integrated circuits (GDICs). Depending on driving schemes, the gate driving circuit 120 may be positioned on only one side, or each of two opposite sides, of the display panel 110. The gate driving circuit 120 may be implemented in a gate-in-panel (GIP) form which is embedded in the bezel area of the display panel 110.

The data driving circuit 130 receives image data DATA from the controller 140 and convert the received image data DATA into an analog data voltage. Then, as the data voltage is output to each data line DL according to the timing when the scan signal is applied through the gate line GL, each subpixel SP connected to the data line DL displays a light emission signal having the brightness corresponding to the data voltage.

Likewise, the data driving circuit 130 may include one or more source driving integrated circuits SDIC, and the source driving integrated circuit SDIC may be connected to the bonding pad of the display panel 110 in a tape automated bonding (TAB) type or a chip-on-glass (COG) type or may be disposed directly on the display panel 110.

In some cases, each source driving integrated circuit SDIC may be integrated and disposed on the display panel 110. Further, each source driving integrated circuit SDIC may be implemented in a chip-on-film (COF) type and, in this case, each source driving integrated circuit SDIC may be mounted on a circuit film and may be electrically connected to the data line DL of the display panel 110 through the circuit film.

The controller 140 supplies various control signals to the gate driving circuit 120 and the data driving circuit 130 and controls the operation of the gate driving circuit 120 and the data driving circuit 130. In other words, the controller 140 may control the gate driving circuit 120 to output a scan signal according to the timing implemented in each frame and, on the other hand, transfers the image data DATA received from the outside to the data driving circuit 130.

In this case, the controller 140 receives, from an external host system 160, several timing signals including, e.g., a vertical synchronization signal Vsync, a horizontal synchronization signal Hsync, a data enable signal DE, and a main clock MCLK, together with the image data DATA. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel.

The host system 160 may be any one of a television (TV) system, a set-top box, a navigation system, a personal computer (PC), a home theater system, a mobile device, and a wearable device.

Accordingly, the controller 140 may generate a control signal according to various timing signals received from the host system 160 and transfers the control signal to the gate driving circuit 120 and the data driving circuit 130.

For example, the controller 140 outputs several gate control signals including, e.g., a gate start pulse GSP, a gate clock GCLK, and a gate output enable signal GOE, to control the gate driving circuit 120. The gate start pulse GSP controls the timing at which one or more gate driving integrated circuits GDIC constituting the gate driving circuit 120 start operation. The gate clock GCLK is a clock signal commonly input to one or more gate driving integrated circuits GDIC and controls the shift timing of the scan signal. The gate output enable signal GOE designates timing information about one or more gate driving integrated circuits GDICs.

The controller 140 outputs various data control signals including, e.g., a source start pulse SSP, a source sampling clock SCLK, and a source output enable signal SOE, to control the data driving circuit 130. The source start pulse SSP controls the timing at which one or more source driving integrated circuits SDIC constituting the data driving circuit 130 start data sampling. The source sampling clock SCLK is a clock signal that controls the timing of sampling data in the source driving integrated circuit SDIC. The source output enable signal SOE controls the output timing of the data driving circuit 130.

The controller 140 may be configured to be coupled with various processors, for example, a microprocessor, a mobile processor, an application processor, etc. in accordance with a device mounted therein.

The controller 140 may be implemented in a separate component from the data driving circuit 130, or integrated with the data driving circuit 130, so that the controller 140 and the data driving circuit 130 can be implemented in a single integrated circuit.

The controller 140 may be a timing controller used in the typical display technology or a control apparatus/device capable of additionally performing other control functionalities in addition to the typical function of the timing controller. In one or more exemplary embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like.

The controller 140 may be mounted on a printed circuit board, a flexible printed circuit, or the like, and may be electrically connected to the data driving circuit 130 and the gate driving circuit 120 through the printed circuit board, the flexible printed circuit, and/or the like.

The controller 140 can transmit signals to, and receive signals from, the data driving circuit 130 via one or more predetermined interfaces. For example, such interfaces may include a low voltage differential signaling (LVDS) interface, an embedded clock point-point interface (EPI), a serial peripheral interface (SPI), and the like. However, the present disclosure are not limited thereto.

The display device 100 may further include a power management circuit 150 that supplies various voltages or currents to, e.g., the display panel 110, the gate driving circuit 120, and the data driving circuit 130 or controls various voltages or currents to be supplied.

The power management circuit 150 adjusts the direct current (DC) input voltage Vin supplied from the host system 160, generating power required to drive the display panel 110, the gate driving circuit 120, and the data driving circuit 130.

The subpixel SP is positioned at the intersection between the gate line GL and the data line DL, and a light emitting element may be disposed in each subpixel SP. For example, the organic light emitting diode display may include a light emitting element, such as an organic light emitting diode, in each subpixel SP and may display an image by controlling the current flowing to the light emitting element according to the data voltage.

The display device 100 may be one of various types of devices, such as liquid crystal displays, organic light emitting diode displays, or plasma display panels, however, the present disclosure is not limited thereto.

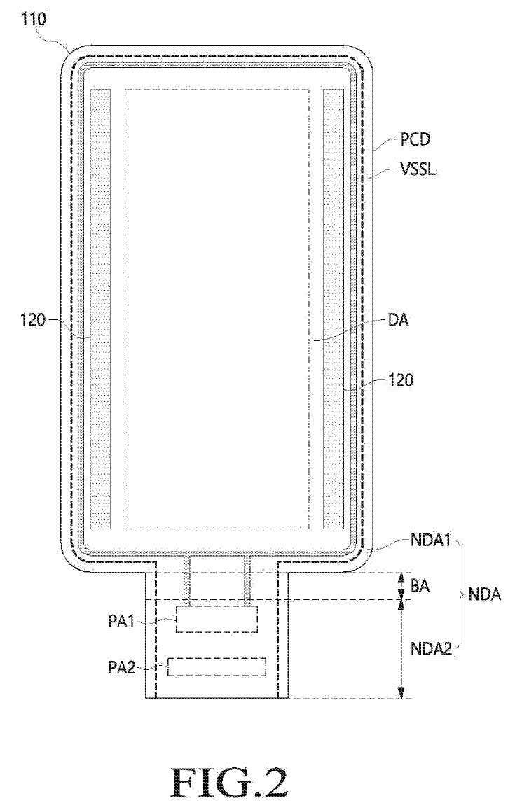

FIG. 2 is a plan view illustrating a display device 100 according to one or more embodiments of the present disclosure.

Referring to FIG. 2, the substrate 111 of the display panel 110 according to one or more embodiments of the present disclosure may include a display area DA and a non-display area NDA. The display area DA and the non-display area NDA may be areas of the display panel 110.

All of the lines and electrodes are formed on the substrate 111. In the display device 100 according to one or more embodiments of the present disclosure, the substrate 111 may be a flexible substrate capable of bending. In the present disclosure, "bending" may have a meaning equivalent to "folding" or "flexible." For example, the substrate may include a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS), and the present disclosure is not limited thereto.

The non-display area NDA is an area where an image is not displayed, and may be an area except for the display area DA. The subpixel SP is not disposed in the non-display area NDA. However, at least one dummy subpixel that is not directly involved in image display may be disposed in the non-display area NDA.

The non-display area NDA may include a first non-display area NDA1, a bending area BA, and a second non-display area NDA2.

The first non-display area NDA1 may be positioned around the display area DA, and may be an area closest to the display area DA among the first non-display area NDA1, the bending area BA, and the second non-display area NDA2.

The second non-display area NDA2 may include pad areas PA1 and PA2 where various pads are disposed, and may be an area farthest from the display area DA among the first non-display area NDA1, the bending area BA, and the second non-display area NDA2.

The bending area BA is an area where the substrate 111 is bent, and may be an area positioned between the first non-display area NDA1 and the second non-display area NDA2.

The substrate 111 may include a display area DA in which images are displayed and a non-display area NDA which is an area outside of the display area DA. A plurality of subpixels SP may be disposed in the display area DA. The non-display area NDA may include a gate in panel (GIP) area where a GIP-type gate driving circuit is formed, a bending area BA where various lines pass and a data driving circuit is electrically connected, and a second non-display area NDA2.

For example, the gate in panel (GIP) area may be positioned in the left outer area and/or the right outer area of the display area DA. The non-display area NDA may be positioned in an upper outer area (or a lower outer area) of the display area DA. The bending area BA may be an area further outside than the second non-display area NDA2, and the printed circuit board may be electrically connected to the bending area BA.

As described above, the substrates (SUB) 111 may include a bending area BA that is bent and folded, and the bending area BA may be folded to be positioned on the lower surface of the unfolded portion. The bending area BA is a partial area of the non-display area NDA, and may be positioned in the driving circuit area to which the data driving circuit is electrically connected and between the driving circuit area and the display area DA.

According to the structure of the subpixel SP, for driving the subpixel SP, a plurality of driving voltage lines DVL for supplying the driving voltage VDD to the subpixel SP and one or more base voltage lines VSSL for applying the base voltage VSS to the common electrode CE of the light emitting element ED in each subpixel SP may be further disposed on the substrates (SUB) 111.

Referring to FIG. 2, e.g., the plurality of driving voltage lines DVL may be disposed in the column direction, but the present disclosure is not limited thereto. In order to efficiently transfer the driving voltage VDD to the plurality of driving voltage lines DVL, a driving voltage pattern integrally or electrically connected to the plurality of driving voltage lines DVL may be disposed in the non-display area NDA.

The plurality of driving voltage lines DVL may electrically connect the bending area BA to the data driving circuit or the printed circuit board connected to the pad areas PA1 and PA2 through the driving voltage pattern.

One or more base voltage lines VSSL may be disposed in the non-display area NDA to surround an outer area of the display area DA for efficient transfer of the base voltage VSS. Further, one or more base voltage lines VSSL may be electrically connected to the data driving circuit or the printed circuit board connected to the driving circuit area past the bending area BA.

A crack prevention pattern PCD may be formed on the substrates (SUB) 111. The crack prevention pattern PCD may be formed outside the base voltage line VSSL in the non-display area NDA, but the present disclosure is not limited thereto.

For example, the crack prevention pattern PCD is a pattern for preventing cracks in lines passing through the substrate SUB 111, and may be formed in a zigzag pattern, but the present disclosure is not limited thereto.

For example, when the bending area BA is bent, some of the signal lines passing through the bending area BA may be cracked (electrically opened) or short-circuited with neighboring signal lines. In this case, an accurate signal may not be transferred through a signal line that is cracked (opened) or short-circuited, and thus a problem with display driving or an image display may not be properly performed, and thus image quality may be greatly decreased. Thus, to prevent such issues, the crack prevention pattern PCD may be disposed, but the present disclosure is not limited thereto.

In the above-described display panel 110, as the flexible substrate (SUB) 111 is used, and the bending area BA which is a portion to which the data driving circuit is connected is bent, a portion of the substrate (SUB) 111 is folded backward. The folded bending area BA which is a portion which an image cannot be displayed is not visible from the front. Accordingly, use of a bending structure and a line arrangement structure may significantly reduce the bezel size, and the narrow bezel design may provide a high aesthetic design.

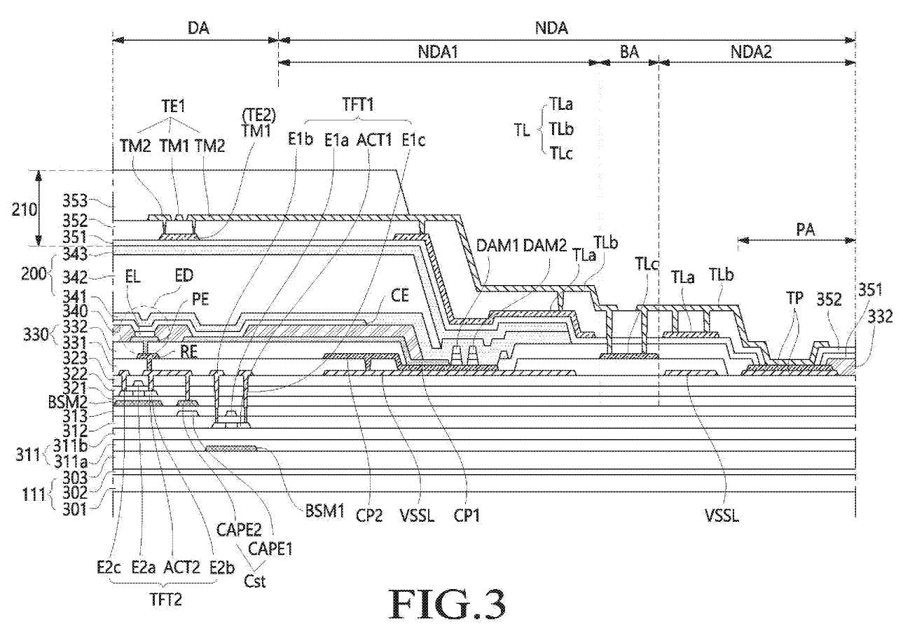

FIG. 3 is a cross-sectional view illustrating a display device 100 according to one or more embodiments of the present disclosure.

Referring to FIG. 3, the display panel 110 according to one or more embodiments of the present disclosure may include a substrate 111, a transistor unit, a light emitting element unit, and an encapsulation unit, but embodiments of the present disclosure are not limited thereto.

The substrate 111 may be a single layer or multiple layers. When the substrate 111 includes multiple layers, the substrate 111 may include a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer, but embodiments of the present disclosure are not limited thereto. The intermediate substrate layer 302 may be an inorganic insulation layer, but embodiments of the present disclosure are not limited thereto. When an electric charge is charged to the first substrate PI1 which is a polyimide layer, the intermediate substrate layer 302 may prevent the electric charge from affecting transistors disposed on the second substrate 303 through the second substrate 303 which is a polyimide layer.

Further, the intermediate substrate layer 302 may prevent a moisture component from penetrating upward through the first substrate 301. For example, the intermediate substrate layer 302 may be formed of a single layer of silicon nitride (SiNx) or silicon oxide (SiOx) or multiple layers thereof, or may be formed of a double layer of silicon dioxide (SiO₂) and silicon nitride (SiNx), but is not limited thereto.

The transistor unit may include insulation layers 311, 312, 313, 321, 322, and 323 on the substrate 111, thin film transistors TFT1 and TFT2, a storage capacitor Cst, and various electrodes or signal lines.

Active layers of the thin-film transistors may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The thin film transistors TFT1 and TFT2 included in the transistor unit may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the present disclosure are not limited thereto.

The first active layer ACT1 may include a first semiconductor material. For example, the first semiconductor material may include an oxide semiconductor, amorphous silicon, polysilicon, or low temperature polysilicon (LTPS), but embodiments of the present disclosure are not limited thereto. The first thin film transistor TFT1 may be implemented as a p-channel transistor or an n-channel thin film transistor, but embodiments of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the present disclosure are not limited thereto.

The second active layer ACT2 may include a second semiconductor material. For example, the second semiconductor material may include an oxide semiconductor, amorphous silicon, polysilicon, or low temperature polysilicon (LTPS), but embodiments of the present disclosure are not limited thereto. The second thin film transistor TFT2 may be implemented as a p-channel thin transistor or an n-channel thin film transistor, but embodiments of the present disclosure are not limited thereto.

The type of the semiconductor material of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. As another example, the first active layer ACT1 of the first thin film transistor TFT1 and the second active layer ACT2 of the second thin film transistor TFT2 may include a low-temperature polysilicon semiconductor material. As another example, the first active layer ACT1 of the first thin film transistor TFT1 may include a low-temperature polysilicon semiconductor material, and the second active layer ACT2 of the second thin film transistor TFT2 may include an oxide semiconductor material. As another example, the first active layer ACT1 of the first thin film transistor TFT1 may include an oxide semiconductor material, and the second active layer ACT2 of the second thin film transistor TFT2 may include a low-temperature polysilicon semiconductor material.

The purposes of the transistors in the display area DA may be as follows.

For example, all of the transistors in each subpixel SP may be implemented as first thin film transistors TFT1. As another example, all of the transistors in each subpixel SP may be implemented as second thin film transistors TFT2. As another example, some of all of the transistors in each subpixel SP may be implemented as first thin film transistors TFT1, and the others of the transistors may be implemented as second thin film transistors TFT2. For example, each subpixel SP may include at least one first thin film transistor TFT1 and at least one second thin film transistor TFT2.

When some of all of the transistors in each subpixel SP are implemented as first thin film transistors TFT1 and the others are implemented as second thin film transistors TFT2, the following examples may be possible.

For example, in each subpixel SP, the driving transistor DT may be implemented as a first thin film transistor TFT1, and other transistors (e.g., the scan transistor ST, the emission control transistor, etc.) than the driving transistor DT may be implemented as second thin film transistors TFT2, but not limited thereto.

As another example, in each subpixel SP, the driving transistor DT may be implemented as a second thin film transistor TFT2, and other transistors (e.g., the scan transistor, the emission control transistor, etc.) than the driving transistor DT may be implemented as first thin film transistors TFT1.

The second thin film transistor TFT2 connected to the pixel electrode PE of the light emitting element ED may be a driving transistor DT or a transistor different from the driving transistor DT according to the configuration of the subpixel circuit SPC. For example, the second thin film transistor TFT2 connected to the pixel electrode PE of the light emitting element ED may be an emission control transistor connected between the driving transistor DT and the light emitting element ED.

The purposes of the transistors in the non-display area NDA may be as follows.

For example, the active layers of the transistors included in the gate-in-panel (GIP) type gate driving circuit may be formed of an oxide semiconductor material. As another example, the active layers of the transistors included in the gate-in-panel (GIP) type gate driving circuit may be formed of a low-temperature polysilicon semiconductor material. As another example, among the transistors included in the gate-in-panel (GIP) type gate driving circuit, some active layers may be formed of a low-temperature polysilicon semiconductor material, and other active layers may be formed of an oxide semiconductor material.

The second active layer ACT2 of the second thin film transistor TFT2 may be positioned higher from the substrate 111 than the first active layer ACT1 of the first thin film transistor TFT1.

The first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be positioned on the first buffer layer 311, and the second active layer ACT2 of the second thin film transistor TFT2 may be positioned on the second buffer layer 321. The second buffer layer 321 may be positioned higher than the first buffer layer 311.

The storage capacitor Cst may be disposed in various metal layers in the display panel 110. For example, the storage capacitor Cst may include a first capacitor electrode CAPE1 and a second capacitor CAPE2.

The light emitting element portion may include a plurality of light emitting elements ED disposed on the planarization layer 330. Each of the light emitting elements ED may include a pixel electrode PE, an intermediate layer EL, and a common electrode CE.

The encapsulation unit may include an encapsulation layer 200 on the plurality of light emitting elements ED. The encapsulation layer 200 may be a single layer or multiple layers, but embodiments of the present disclosure are not limited thereto. For example, the encapsulation layer may include a first inorganic encapsulation layer, a first organic encapsulation layer, and a second inorganic encapsulation layer, Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

In addition to the encapsulation layer 200, the encapsulation unit may further include at least one dam DAM for preventing a material constituting the encapsulation layer 200 from overflowing. In particular, when the second encapsulation layer 342 included in the encapsulation layer 200 is an organic encapsulation layer formed of an organic material, the dam DAM may prevent the organic material from overflowing.

Hereinafter, a structure or a vertical structure of the display panel 110 according to one or more embodiments of the present disclosure is described in more detail.

The first buffer layer 311 may be disposed on the substrate 111. The first buffer layer 311 may be a single layer or multiple layers, but embodiments of the present disclosure are not limited thereto. When the first buffer layer 311 includes multiple layers, the first buffer layer 311 may include a lower buffer layer 311a and an upper buffer layer 311b. Each of the lower buffer layer 311a and the upper buffer layer 311b may be a silicon oxide (SiOx) film, a silicon nitride (SiNx) film or silicon oxynitride (SiON) film, but not limited thereto.

The first active layer ACT1 of the first thin film transistor TFT1 may be disposed on the first buffer layer 311. The first active layer ACT1 may include a channel area in which a channel is formed, a source connection area on one side of the channel area, and a drain connection area on the other side of the channel area.

The first gate insulation layer 312 may be disposed on the first active layer ACT1 of the first thin film transistor TFT1. The first gate electrode E1a of the first thin film transistor TFT1 may be disposed on the first gate insulation layer 312. The first inter-layer insulation layer 313 may be disposed on the first gate electrode E1a of the first thin film transistor TFT1. For example, each of the first gate insulation layer 312 and the first inter-layer insulation layer 313 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. Here, the metal layer where the first gate electrode E1a of the first thin film transistor TFT1 is disposed may be referred to as a gate metal layer.

The second buffer layer 321 may be disposed on the first inter-layer insulation layer 313.

The second active layer ACT2 of the second thin film transistor TFT2 may be disposed on the second buffer layer 321. The second active layer ACT2 may include a channel area in which a channel is formed, a source connection area on one side of the channel area, and a drain connection area on the other side of the channel area.

The second gate insulation layer 322 may be disposed on the second active layer ACT2 of the second thin film transistor TFT2. The second gate electrode E2a of the second thin film transistor TFT2 may be disposed. The second inter-layer insulation layer 323 may be disposed on the second gate electrode E2a of the second thin film transistor TFT2. For example, each of the second gate insulation layer 322 and the second inter-layer insulation layer 323 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. Here, the second gate electrode E2a of the second thin film transistor TFT2 may be referred to as a second gate metal layer.

The first source electrode E1b and the first drain electrode E1c of the first thin film transistor TFT1, and the second source electrode E2b and the second drain electrode E2c of the second thin film transistor TFT2 may be disposed on the second interlayer insulation layer 323.

The first source electrode E1b and the first drain electrode E1c of the first thin film transistor TFT1 may be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second thin film transistor TFT2 may be connected to the source connection area and the drain connection area, respectively, of the second active layer ACT2 through the holes of the second inter-layer insulation layer 323 and the second gate insulation layer 322.

The first source electrode E1b and the first drain electrode E1c of the first thin film transistor TFT1, and the second source electrode E2b and the second drain electrode E2c of the second thin film transistor TFT2 may include a first source-drain metal and may be disposed in the first source-drain metal layer.

For example, the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first thin film transistor TFT1 on the first gate insulation layer 312 and may be disposed in the first gate metal layer, but embodiments of the present disclosure are not limited thereto. For example, the second capacitor electrode CAPE2 may be disposed on the first inter-layer insulation layer 313.

The second source electrode E2b of the second thin film transistor TFT2 may be electrically connected to the second capacitor electrode CAPE2 through holes of the second inter-layer insulation layer 323, the second gate insulation layer 322, and the second buffer layer 321.

The transistor unit may further include a first shield pattern BSM1 disposed on the substrate 111. The first shield pattern BSM1 may overlap the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311, or may be disposed between the lower buffer layer 311a and the upper buffer layer 311b.

The transistor unit may further include a second shield pattern BSM2 disposed on the substrate 111. The second shield pattern BSM2 may overlap the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first insulation layer 313 and the second buffer layer 321. The second shield pattern BSM2 may be disposed in the same metal layer as the second capacitor CAPE2, but embodiments of the present disclosure are not limited thereto. As another example, the second shield pattern BSM2 may be disposed in the same first gate metal layer as the first gate electrode E1a of the first thin film transistor TFT1.

The planarization layer 330 may be disposed on the first thin film transistor TFT1 and the second thin film transistor TFT2, and may be disposed under the light emitting element ED. The planarization layer 330 may be an organic insulation layer including an organic insulating material.

For example, the planarization layer 330 may be constituted of one layer. As another example, the planarization layer 330 may include two layers. The planarization layer 330 may include a first planarization layer 331 and a second planarization layer 332. As another example, the planarization layer 330 may include three or more layers. However, embodiments of the present disclosure are not limited thereto.

The first planarization layer 331 may be disposed on the first source electrode E1b and the first drain electrode E1c of the first thin film transistor TFT1, and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed while covering both the first thin film transistor TFT1 and the second thin film transistor TFT2.

A connection electrode RE may be disposed on the first planarization layer 331. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through the hole of the first planarization layer 331. The second source electrode E2b of the second thin film transistor TFT2 may be electrically connected to the second capacitor electrode CAPE2 of the storage capacitor Cst.

The connection electrode RE may be disposed in the second source-drain metal layer on the first planarization layer 331 and may include a second source-drain metal.

The second planarization layer 332 may be disposed on the connection electrode RE.

The light emitting element unit may be disposed on the second planarization layer 332. The light emitting element ED may be formed on the second planarization layer 332. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the second planarization layer 332. The pixel electrode PE may be electrically connected to the connection electrode RE through the hole of the second planarization layer 332.

A bank 340 may be disposed on the pixel electrode PE. The opening of the bank 340 may expose a portion of the pixel electrode PE to form the emission area. The opening of the bank 340 may overlap a portion of the pixel electrode PE.

For example, the bank 340 may be formed of a material including a black pigment, or an organic material such as a benzocyclobutene resin, a polyimide resin, an acrylic resin, or a photosensitive polymer, but embodiments of the present disclosure are not limited thereto. When the bank 340 is formed of a material including a black pigment, a black dye, or the like, it may be a black bank. When the bank 340 is formed of a material including a black pigment or a black dye, light from the outside may be blocked or light reflected from the outside may be blocked, and thus the luminance of the display device 100 may be further enhanced.

The intermediate layer EL of the light emitting element ED may be disposed on a portion of the pixel electrode PE and the bank 340. The common electrode CE may be disposed on the intermediate layer EL.

The encapsulation unit may be disposed on the light emitting element unit and may be positioned on the common electrode CE. The encapsulation unit may include the encapsulation layer 200 formed on the common electrode CE.

The encapsulation layer 200 may prevent moisture or oxygen from penetrating into the light emitting element ED. For example, the encapsulation layer 200 may prevent moisture or oxygen from penetrating into the organic material included in the intermediate layer EL of the light emitting element ED. The encapsulation layer 200 may be formed of a single layer or multiple layers, but embodiments of the present disclosure are not limited thereto.

For example, the encapsulation layer 200 may include a first encapsulation layer 341, a second encapsulation layer 342, and a third encapsulation layer 343, but embodiments of the present disclosure are not limited thereto. For example, the first encapsulation layer 341 and the third encapsulation layer 343 may include an inorganic layer, and the second encapsulation layer 342 may include an organic layer, but embodiments of the present disclosure are not limited thereto.

The display panel 110 according to one or more embodiments of the present disclosure may have a built-in touch sensor. In this case, the display panel 110 according to one or more embodiments of the present disclosure may include a touch sensor layer 210 disposed on the encapsulation layer 200 and having a touch sensor.

The touch sensor layer 210 may include a plurality of touch electrodes TE corresponding to touch sensors, and may include at least one touch metal layer for forming the plurality of touch electrodes TE.

For example, the touch sensor layer 210 may include a first touch metal layer on which a plurality of first touch metals TM1 are disposed, and a second touch metal layer on which a plurality of second touch metals TM2 are disposed, to form the plurality of touch electrodes TE. In this case, the touch sensor layer 210 may further include a touch interlayer insulation layer 352 disposed between the first touch metal layer and the second touch metal layer.

For example, one of the first touch metal layer and the second touch metal layer may be a sensor metal layer and the other may be a bridge metal layer.

For example, the first touch metal layer may be a bridge metal layer, and the second touch metal layer may be a sensor metal layer. In this case, the plurality of second touch metals TM2 disposed in the second touch metal layer may be sensor metals forming touch sensors, and the plurality of first touch metals TM1 disposed in the first touch metal layer may be bridge metals electrically connecting the plurality of second touch metals TM2, which are sensor metals. For example, two or more second touch metals TM2 and at least one first touch metal TM1 may constitute one first touch electrode TE1. In this case, two or more second touch metals TE2 may be electrically connected by at least one first touch metal TM1.

As another example, the first touch metal layer may be a sensor metal layer, and the second touch metal layer may be a bridge metal layer. In this case, the plurality of first touch metals TM1 disposed in the first touch metal layer may be sensor metals forming touch sensors, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this case, the plurality of first touch metals TM1 disposed in the first touch metal layer may include sensor metals and bridge metals, and the plurality of second touch metals TM2 disposed in the second touch metal layer may include sensor metals and bridge metals.

The touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulation layer 352 may be disposed on the first touch metal layer.

The touch sensor layer 210 may further include a touch protection layer 353 disposed to cover the touch metal layer. For example, the touch protection layer 353 may be disposed on the second touch metal layer.

For example, the touch buffer layer 351 may be an inorganic layer including an inorganic insulating material or an organic layer including an organic insulating material, the touch interlayer insulation layer 352 may be an inorganic layer including an inorganic insulating material or an organic layer including an organic insulating material, and the touch protection layer 353 may be an inorganic layer including an inorganic insulating material or an organic layer including an organic insulating material.

For example, at least one of the touch buffer layer 351 and the touch interlayer insulation layer 352 may extend from the display area DA to the non-display area NDA. The touch protection layer 353 may be disposed to extend from the display area DA to the non-display area NDA.

The touch routing line TL may electrically connect the touch electrode TE and the touch pad TP. The touch routing line TL may be formed of at least one of the first touch metal TM1 and the second touch metal TM2.

For example, the touch routing line TL may be formed of the first touch metal TM1, or the touch routing line TL may be formed of the second touch metal TM2, or the touch routing line TL may be formed of the first touch metal TM1 and the second touch metal TM2. When one touch routing line TL is formed of the first touch metal TM1 and the second touch metal TM2, the first touch metal TM1 and the second touch metal TM2 constituting one touch routing line TL may be electrically connected through a hole in the insulation layer 352.

For example, one touch routing line TL may include a plurality of wiring sections, and each of the plurality of wiring sections may be a single wiring section or a double wiring section. Here, the single wiring section may be a wiring section having one signal path, and the double wiring section may be a wiring section where two signal paths are connected in parallel.

The touch routing line TL may be disposed along the inclined surface of the encapsulation layer 200, and may extend to the touch pad TP through the upper portion of the dam DAM1 and DAM2.

The touch buffer layer 351 may have an opening exposing at least a portion of the touch pad TP. The touch routing line TL may be electrically connected to the touch pad TP through the opening of the touch buffer layer 351. The touch interlayer insulation layer 352 may be disposed on the touch routing line TL, and may extend to an area where the touch pad TP is disposed. The touch protection layer 353 may be disposed only in the display area DA, or may extend to the non-display area NDA to be disposed on the touch routing line TL. In some cases, the touch protection layer 353 may further extend to the upper portion of the touch pad TP.

Each of the plurality of touch electrodes TE may be a mesh-type electrode having a plurality of openings. In this case, each of the plurality of touch electrodes TE may be formed of at least one second touch metal TM2. However, embodiments of the present disclosure are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1, which are bridge metals. For example, the two second touch metals TM2 spaced apart from each other may be electrically connected by the first touch metal TM1 to constitute one first touch electrode TE1.

The plurality of first touch metals TM1 and the plurality of second touch metals TM2 may be disposed not to overlap the light emitting element ED. The plurality of first touch metals TM1 and the plurality of second touch metals TM2 may overlap the bank 340. Accordingly, the luminous efficiency of the light emitting element ED may increase.

The touch routing line TL may connect the touch pad TP disposed in the pad area PA in the second non-display area NDA2 and the first touch electrode TE1 disposed in the display area DA. To that end, the touch routing line TL may be disposed across the second non-display area NDA2, the bending area BA, and the first non-display area NDA1.

The touch routing line TL may include a first line section TLa, a second line section TLb, and a third line section TLc. For example, the touch routing line TL may include the first line section TLa and the second line section TLb disposed in the first non-display area NDA1 and the second non-display area NDA2, and the third line section TLc disposed in the bending area BA. The third line section TLc may connect the first line section TLa and the second line section TLb.

The first line section TLa of the touch routing line TL is a single line section, and may further include a third touch metal layer where the third touch metal TM3 is disposed.

The first line section TLa of the touch routing line TL may extend along the inclined surface of the encapsulation layer 200 and may extend via the upper portion of at least one dam DAM1 or DAM2.

For example, the first line section TLa of the touch routing line TL may lead to the third line section TLc of the touch routing line TL through at least one of the first touch metal layer and the second touch metal layer.

The second line section TLb of the touch routing line TL may include at least one of a first touch metal layer where the first touch metal TM1 is disposed and a second touch metal layer where the second touch metal TM2 is disposed.

For example, the second line section TLb of the touch routing line TL may be formed of a second touch metal layer. As another example, the second line section TLb of the touch routing line TL may be configured by electrically connecting the first touch metal layer and the second touch metal layer.

For example, the second line section TLb of the touch routing line TL may be electrically connected to the touch pad TP through a contact hole (opening) that penetrates the second planarization layer 332, the touch buffer layer 351, and the touch interlayer insulation layer 352.

For example, the third line section TLc of the touch routing line TL may lead to the second line section TLb of the touch routing line TL.

The third line section TLc of the touch routing line TL may include a metal layer different from the first to third touch metal layers where the first to third touch metals TM1, TM2, and TM3 are disposed. For example, the metal layer included in the third line section TLc of the touch routing line TL may be the same as the metal layer where the electrode or line for display driving is disposed. For example, the metal layer included in the third line section TLc of the touch routing line TL may include a metal layer where the pixel electrode PE is disposed, but the present disclosure is not limited thereto.

The touch pad TP is electrically connected to the second line section TLb of the touch routing line TL, and may include a metal layer different from the first to third touch metal layers. For example, the metal layer included in the touch pad TP may be the same as the metal layer where the electrode or line for display driving is disposed. For example, the metal layer included in the touch pad TP may include a metal layer where the pixel electrode PE is disposed, but the present disclosure is not limited thereto.

The display panel 110 according to one or more embodiments of the present disclosure may further include a common voltage line VSSL to which the common voltage VSS is applied and a connection pattern CP connecting the common electrode CE and the common voltage line VSSL. For example, the connection pattern CP may include the same material as that of the pixel electrode PE. For example, the connection pattern CP may include a first connection pattern CP1 and a second connection pattern CP2. For example, the first connection pattern CP1 may connect the common electrode CE and the second connection pattern CP2, and the second connection pattern CP2 may connect the first connection pattern CP1 and the common voltage line VSSL, but embodiments of the present disclosure are not limited thereto.

As described above, delamination or cracks may occur at the end of the touch buffer layer due to the laser trimming line in the edge area of the bending area BA, where the printed circuit board is bent to the rear surface, and the first non-display area NDA1 around the bending area BA in the non-display area NDA of the display panel 110, causing moisture penetration and hence increasing defects, such as gate drain short (GDS) defects.

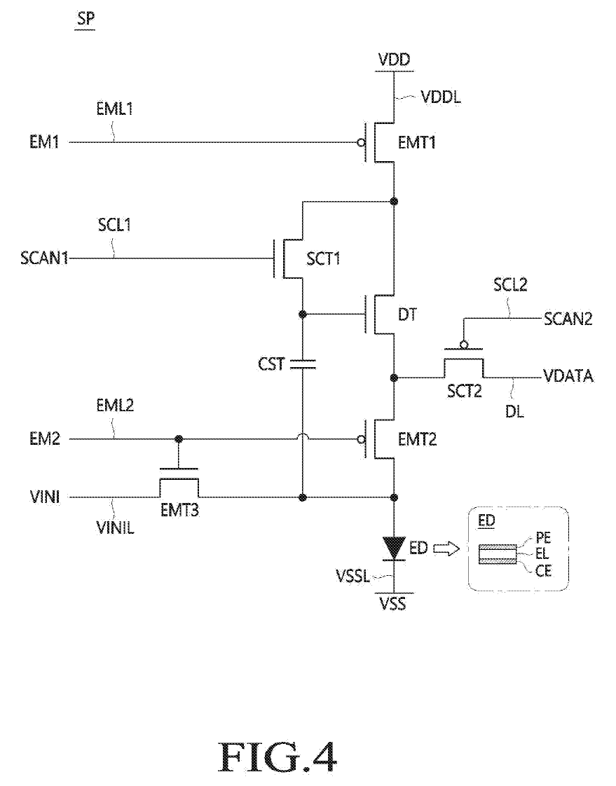

FIG. 4 is an example view illustrating a subpixel SP according to one or more embodiments of the present disclosure.

FIG. 4 is a view illustrating an example circuit structure of a subpixel SP disposed in a display device 100 according to one or more embodiments of the present disclosure.

Referring to FIG. 4, in the subpixel SP of the display device 100 according to one or more embodiments of the present disclosure, e.g., a light emitting element ED, a plurality of transistors for driving the light emitting element ED, and one capacitor CST may be disposed.

In other words, the embodiment illustrated in FIG. 4 shows a subpixel SP composed of 6T1C as an example, but circuit elements disposed in the subpixel SP may be variously implemented according to the type of display device 100, each of the plurality of subpixels may further include a compensation circuit. In this case, each of the plurality of subpixels may have various structures such as 4T2C, 5T2C, 6T2C, 7T1C, 7T2C, and the like.

The case where the driving transistor DT, the first scan transistor SCT1, and the third emission control transistor EMT3 disposed in the subpixel SP are N-type, and the first emission control transistor EMT1, the second scan transistor SCT2, and the second emission control transistor EMT2 are P-type is illustrated as an example, but in some cases, the subpixel SP may be composed of different types of transistors.

The configuration of the active layers of the plurality of transistors disposed in the subpixel SP may vary. For example, the active layer may be formed of a poly-silicon semiconductor. The transistor TR including the active layer is referred to as a low-temperature polycrystalline silicon (LTPS) transistor.

For example, the active layer may be formed of an oxide semiconductor. The transistor including the active layer may be referred to as an oxide transistor or an oxide semiconductor transistor. In this case, e.g., the oxide semiconductor may be an N-type oxide semiconductor such as IGZO, IZO, or ITZO, or a P-type oxide semiconductor such as CuOx, SnOx, or NiOx.

The case where the driving transistor DT, the first scan transistor SCT1, and the third emission control transistor EMT3 disposed in the subpixel SP are oxide semiconductor transistors, and the first emission control transistor EMT1, the second scan transistor SCT2, and the second emission control transistor EMT2 are LTPS transistors is illustrated as an example, but in some cases, the configuration of the active layer of the transistor may be changed.

When the subpixel SP is formed of 6T1C, six transistors and one capacitor CST may be disposed in each subpixel SP.

The driving transistor DT may have a drain node, a gate node, and a source node. The drain node or the source node may be electrically connected to the driving voltage line VDDL. The source node or the drain node may be electrically connected to the anode electrode of the light emitting element ED.

The first scan transistor SCT1 may be controlled by the first scan signal SCAN1 applied to the first scan line SCL1, and may be electrically connected between the drain node and the gate node of the driving transistor DT.

The second scan transistor SCT2 may be controlled by the second scan signal SCAN2 applied to the second scan line SCL2, and may be electrically connected to the data line DL to which the data voltage VDATA is applied, and the source node or the drain node of the driving transistor DT.

The first emission control transistor EMT1 may be controlled by the first emission control signal EM1 applied to the first emission control line EML1, and may be electrically connected between the driving voltage line VDDL and the drain node or the source node of the driving transistor DT.

The second emission control transistor EMT2 may be controlled by the second emission control signal EM2 applied to the second emission control line EML2, and may be electrically connected between the source node or drain node of the driving transistor DT and the anode electrode of the light emitting element ED.

The third emission control transistor EMT3 may be controlled by the second emission control signal EM2 applied to the second emission control line EML2, and may be electrically connected between the initialization voltage line VINIL and the anode electrode of the light emitting element ED. The third emission control transistor EMT3 may be referred to as an "initialization transistor".

The capacitor CST is electrically connected between the gate node of the driving transistor DT and the anode electrode of the light emitting element ED, and may maintain the data voltage VDATA for one frame.

The light emitting element ED may be electrically connected between the anode electrode of the light emitting element ED and the base voltage line VSSL to which the base voltage VSS is applied, and may be, e.g., an organic light emitting diode (OLED).

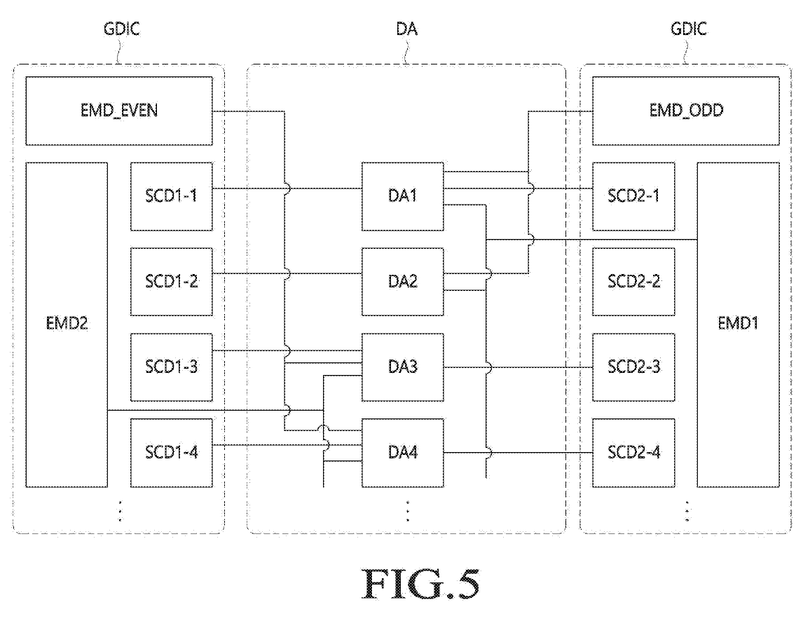

FIG. 5 is a view illustrating a connection relationship between a gate driving integrated circuit GDIC and a display area DA according to one or more embodiments of the present disclosure.

Referring to FIG. 5, the display device 100 may include a display area DA where a plurality of subpixels SP are disposed, and a gate driving integrated circuit GDIC disposed on two opposite sides of the display area DA. As the gate driving integrated circuit GDIC disposed on one side, a plurality of emission control drivers EMD2, EMD4, EMD6 … may be disposed. As the gate driving integrated circuit GDIC disposed on the other side, a plurality of emission control drivers EMD1, EMD3, EMD5… may be disposed. However, the present disclosure is not limited thereto.

The display area DA may include a first display area DA1, a second display area DA2, a third display area DA3, and a fourth display area DA4. Further, the display area DA may include more Nth display area according to the resolution. For example, the display area DA may include the first display area DA1 to the 2160th display area DA2160, when the display device 100 having a resolution of 2,160 X 3,840 sequentially outputs scan signals to the first gate line to the 2160th gate line GL. In other words, the display device 100 may include a plurality of display areas DA1 to DA2160. However, a resolution of the display device 100 is not limited to 2,160 X 3,840, and the display areas are also not limited to display areas DA1 to DA2160.

The plurality of subpixels SP may be disposed in the form of a matrix in the display area DA. The first display area DA1 may be an area where a plurality of subpixels SP disposed in the first row of the display area DA are positioned. The second display area DA2 may be an area where a plurality of subpixels SP disposed in the second row of the display area DA are positioned. The third display area DA3 may be an area where a plurality of subpixels SP disposed in the third row of the display area DA are positioned. The fourth display area DA4 may be an area where a plurality of subpixels SP disposed in the fourth row of the display area DA are positioned. However, the present disclosure is not limited thereto. For example, the first display area DA1 may be an area where a plurality of subpixels SP disposed in the first column of the display area DA are positioned. The second display area DA2 may be an area where a plurality of subpixels SP disposed in the second column of the display area DA are positioned. The third display area DA3 may be an area where a plurality of subpixels SP disposed in the third column of the display area DA are positioned. The fourth display area DA4 may be an area where a plurality of subpixels SP disposed in the fourth column of the display area DA are positioned.

The gate driving integrated circuit GDIC may include a first emission control driver EMD1, a second emission control driver EMD2, a 1-1th scan driver SCD1-1, a 1-2th scan driver SCD1-2, a 1-3th scan driver SCD1-3, a 1-4th scan driver SCD1-4, a 2-1th scan driver SCD2-2, a 2-3th scan driver SCD2-3, and a 2-4th scan driver SCD2-4.

More emission control drivers and scan drivers may be included according to the resolution of the display device 100. The emission control driver (e.g., the first emission control driver EMD1) may output the emission control signal EM. The scan driver (e.g., the 1-1th scan driver SCD1-1) may output the scan signal SCAN.

For example, the plurality of subpixels SP disposed in the first display area DA1 may receive the first scan signal SCAN1 from the 1-1th scan driver SCD1-1 and the second scan signal SCAN2 from the 2-1th scan driver SCD2-1. The plurality of subpixels SP disposed in the second display area DA2 may receive the first scan signal SCAN1 from the 1-2th scan driver SCD1-2, and receive the second scan signal SCAN2 from the 2-2th scan driver SCD2-2. The plurality of subpixels SP disposed in the third display area DA3 may receive the first scan signal SCAN1 from the 1-3th scan driver SCD1-3, and receive the second scan signal SCAN2 from the 2-3th scan driver SCD2-3. The plurality of subpixels SP disposed in the fourth display area DA4 may receive the first scan signal SCAN1 from the 1-4th scan driver SCD1-4, and receive the second scan signal from the 2-4th scan driver SCD2-4.

For example, the first emission control driver EMD1 and the second emission control driver EMD2 may have the same circuit structure as the same driving unit outputting the same type of signal.

The emission drivers may input the first emission control signal EM1 into two paired display areas and the second emission control signal EM2 into two other paired display areas.

For example, the first emission control driver EMD1 may output the first emission control signal EM1 to the plurality of subpixels SP disposed in the first display area DA1 and the second display area DA, and output the second emission control signal EM2 to the plurality of subpixels SP disposed in the fifth display area and the sixth display area.

For example, the second emission control driver EMD2 may output the first emission control signal EM1 to the plurality of subpixels SP disposed in the third display area DA3 and the fourth display area DA4, and output the second emission control signal EM2 to the plurality of subpixels SP disposed in the seventh display area and the eighth display area.

As the first display area DA1 and the second display area DA2 of the display panel 110 are disposed in the first row and the second row, respectively, separate emission control drivers for inputting the second emission control signal EM2 to the first display area DA1 and the second display area DA2 may be required.

Further, as the third and fourth display areas DA3 and DA4 of the display panel 110 are disposed in the third and fourth rows, respectively, separate emission control drivers for inputting the second emission control signal EM2 into the third and fourth display areas DA3-DA4 may be required.

Therefore, emission drivers EMD_EVEN and EMD_ODD for inputting the second emission control signal EM2 to the first to fourth display areas DA1-DA4 may be disposed at the uppermost end of the gate driving integrated circuit GDIC.

The display areas DA5 to DA2160 disposed in the fifth row and the subsequent rows do not require a separate emission driver for receiving the second emission control signal EM2 and may receive the second emission control signal EM2 from the emission control drivers (e.g., EMD1 and EMD2) outputting the first emission control signal EM1.

For example, as the first display area DA1 is an area disposed at the uppermost end of the display panel 110, it may receive the first emission control signal EM1 from the first emission control driver EMD1 and the second emission control signal EM2 from the odd emission control driver EMD_ODD.

As the second display area DA2 is an area disposed in the second row of the display panel 110, it may receive the first emission control signal EM1 from the first emission control driver EMD1, and the second emission control signal EM2 from the odd emission control driver EMD_ODD.

As the third display area DA3 is an area disposed in the third row of the display panel 110, it may receive the first emission control signal EM1 from the second emission control driver EMD2, and the second emission control signal EM2 from the even emission control driver EMD_EVEN.

As the fourth display area DA4 is an area disposed in the fourth row of the display panel 110, it may receive the first emission control signal EM1 from the second emission control driver EMD2, and the second emission control signal EM2 from the even emission control driver EMD_EVEN.

Since the fifth display area DA5 is an area disposed in the fifth row of the display panel 110, it may receive the first emission control signal EM1 from an emission control driver (e.g., the third emission control driver EMD3) disposed under the first emission control driver EMD1, and receive the second emission control signal EM2 from the first emission control driver EMD1.

Since the sixth display area DA6 is an area disposed in the sixth row of the display panel 110, it may receive the first emission control signal EM1 from an emission control driver (e.g., the third emission control driver EMD3) disposed under the first emission control driver EMD1, and receive the second emission control signal EM2 from the first emission control driver EMD1.

Since the seventh display area DA7 is an area disposed in the seventh row of the display panel 110, it may receive the first emission control signal EM1 from an emission control driver (e.g., the fourth emission control driver EMD4) disposed under the second emission control driver EMD2, and receive the second emission control signal EM2 from the second emission control driver EMD2.

Since the eighth display area DA8 is an area disposed in the eighth row of the display panel 110, it may receive the first emission control signal EM1 from an emission control driver (e.g., the fourth emission control driver EMD4) disposed under the second emission control driver EMD2, and receive the second emission control signal EM2 from the second emission control driver EMD2.

An example of the gate driving integrated circuit GDIC illustrated in FIG. 5 may be variously implemented according to the type of the display device 100.

Hereinafter, an equivalent circuit of the emission control driver EMD and its operations are described.

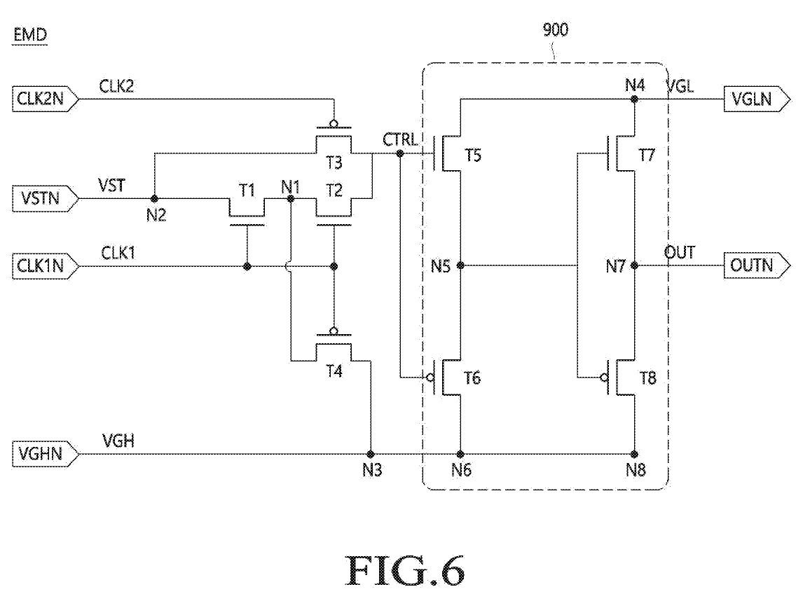

FIG. 6 is an example view illustrating an emission control driver EMD according to one or more embodiments of the present disclosure.

Referring to FIG. 6, the emission control driver EMD may include a first transistor T1, a second transistor T2, a third transistor T3, a fourth transistor T4, an output circuit 900, an output node OUTN, a first clock signal input node CLK1N, a second clock signal input node CLK2N, a start signal input node VSTN, a high level gate voltage input node VGHN, and a low level gate voltage input node VGLN.

The output circuit 900 may include a fifth transistor T5, a sixth transistor T6, a seventh transistor, and an eighth transistor T8. The output circuit 900 may output a gate signal OUT having a high level voltage or a low level voltage according to the voltage state of the control node CTRL connected to the second transistor T2 and the third transistor T3.

In the following example, the first transistor T1, the second transistor T2, the fifth transistor T5, and the seventh transistor T7 are oxide semiconductor transistors, and the third transistor T3, the fourth transistor T4, the sixth transistor T6, and the eighth transistor T8 are LTPS transistors, but the configuration of the active layer of each transistor may be changed.

In the following example, the first transistor T1, the second transistor T2, the fifth transistor T5, and the seventh transistor T7 are N-type transistors, and the third transistor T3, the fourth transistor T4, the sixth transistor T6, and the eighth transistor T8 are P-type transistors, but the type of each transistor may be changed.

As the oxide semiconductor transistor is used in the emission control driver EMD, the emission control driver EMD may be configured without including a component (e.g., a capacitor) for preventing a voltage drop. Further, as the voltage drop is reflected, the gate driving circuit 120 may be driven without increasing the high-level gate voltage VGH or lowering the low-level gate voltage VGL.

The first transistor T1 may include a first node N1, a second node N2, and a first gate node. The first node N1 may be connected to the second transistor T2. The second node N2 may be electrically connected to the start signal input node VSTN, and a start signal VST may be inputted. The first gate node may be electrically connected to the first clock signal input node CLK1N, and the first clock signal CLK1 may be inputted.

The second transistor T2 may include a first node N1, a control node CTRL, and a second gate node. The first node N1 may be connected to the first transistor T1. The control node CTRL may be connected to the third transistor T3, the gate node of the fifth transistor T5, and the gate node of the sixth transistor T6. The second gate node may be electrically connected to the first clock signal input node CLK1N, and the first clock signal CLK1 may be input.

The third transistor T3 may include a second node N2, a control node CTRL, and a third gate node. The third gate node is electrically connected to the second clock signal input node CLK2N, and a second clock signal CLK2 may be input.

The fourth transistor T4 may include a first node N1, a third node N3, and a fourth gate node. The third node N3 may be electrically connected to the high-level gate voltage input node VGHN, and the high-level gate voltage VGH may be input. The third node N3 may be connected to the sixth transistor T6 and the eighth transistor T8.

The fourth gate node may be electrically connected to the first clock signal input node CLK1N, and the first clock signal CLK1 may be input. The fourth transistor T4 may transmit the high level gate voltage VGH input from the high level gate voltage input node VGHN to the first node N1.

The fifth transistor T5 may include a fourth node N4, a control node CTRL, and a fifth node N5. The fourth node N4 may be electrically connected to the low level gate voltage input node VGLN, and the low level gate voltage VGL may be input. The fourth node N4 may be coupled to the drain node of the seventh transistor T7. As the voltage of the control node CTRL is input to the gate node of the fifth transistor T5, the turn-on or turn-off state of the fifth transistor T5 may be determined. The fifth node N5 may be electrically connected to the sixth transistor T6, the gate node of the seventh transistor T7, and the gate node of the eighth transistor T8. Accordingly, the turn-on or turn-off states of the seventh transistor T7 and the eighth transistor T8 may be determined according to the voltage state of the fifth node N5.

The sixth transistor T6 may include a fifth node N5, a sixth node N6, and a control node CTRL. The sixth node N6 may be electrically connected to the high level gate voltage input node VGHN, and the high level gate voltage VGH may be input. As the voltage of the control node CTRL is input to the gate node of the sixth transistor T6, the turn-on or turn-off state of the sixth transistor T6 may be determined.

The seventh transistor T7 may include a fourth node N4, a fifth node N5, and a seventh node N7. As the voltage of the fifth node N5 is input to the gate node of the seventh transistor T7, the turn-on or turn-off state of the seventh transistor T7 may be determined. The seventh node N7 may be electrically connected to the output node OUTN, and the voltage level of the gate signal (e.g., the emission control signal EM) output to the output node OUTN may be determined according to the voltage level of the seventh node N7. For example, as the seventh transistor T7 is turned on, the low level gate voltage VGL may be input to the seventh node N7. Accordingly, the gate signal OUT having the voltage level of the low level gate voltage VGL may be output to the plurality of subpixels SP in the display area DA. The seventh node N7 may be connected to the eighth transistor T8.

The eighth transistor T8 may include a fifth node N5, a seventh node N7, and an eighth node N8. As the voltage of the fifth node N5 is input to the gate node of the eighth transistor T8, the turn-on or turn-off state of the eighth transistor T8 may be determined. The eighth node N8 may be electrically connected to the high level gate voltage input node VGHN, and the high level gate voltage VGH may be input. For example, as the eighth transistor T8 is turned on, the high level gate voltage VGH may be input to the seventh node N7. Accordingly, the gate signal OUT having the voltage level of the high level gate voltage VGH may be output to the plurality of subpixels SP in the display area DA.

Hereinafter, the operation of the equivalent circuit of the emission control driver EMD is described.

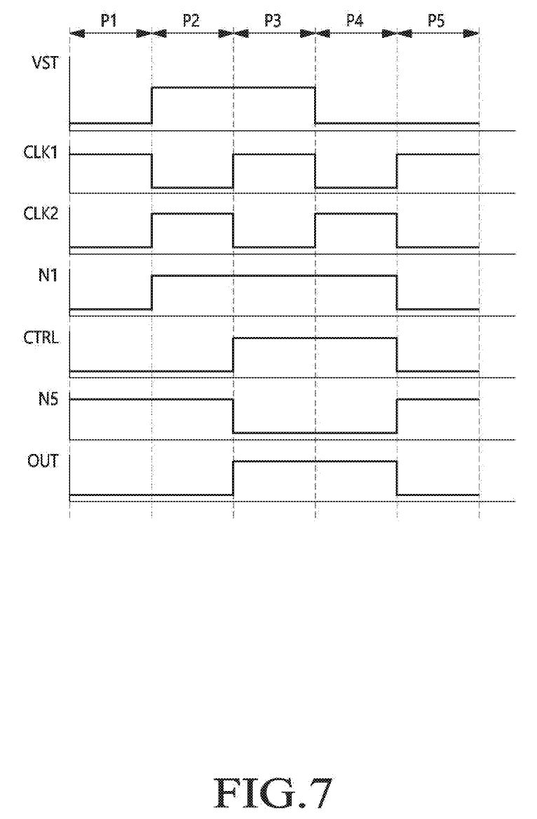

FIG. 7 is a timing diagram illustrating an emission control driver EMD according to one or more embodiments of the present disclosure. The timing diagram shows voltages of the start signal VST, the first clock signal CLK1, the second clock signal CLK2, the first node N1, the fifth node N5, the control node CTRL and the gate signal OUT, during a first driving period P1, a second driving period P2, a third driving period P3, a fourth driving period P4, and a fifth driving period P5.

Referring to FIG. 7, the driving period of the emission control driver EMD includes the first driving period P1, the second driving period P2, the third driving period P3, the fourth driving period P4, and the fifth driving period P5. In all of the driving periods of the emission control driver EMD, the first clock signal CLK1 and the second clock signal CLK2 have opposite phases. The low level voltage of the gate signal OUT may be the low level gate voltage VGL, and the high level voltage of the gate signal OUT may be the high level gate voltage VGH.

During the first driving period P1, the start signal VST may have a low level voltage. The first clock signal CLK1 may have a high level voltage. The second clock signal CLK2 may have a low level voltage. The voltage of the first node N1 may have a low level voltage. The voltage of the control node CTRL may have a low level voltage. The voltage of the fifth node N5 may have a high level voltage. The gate signal OUT may have a low level voltage.

During the second driving period P2, the start signal VST may have a high level voltage. The first clock signal CLK1 may have a low level voltage. The second clock signal CLK2 may have a high level voltage. The voltage of the first node N1 may have a high level voltage. The voltage of the control node CTRL may have a low level voltage. The voltage of the fifth node N5 may have a high level voltage. The gate signal OUT may have a low level voltage.

During the third driving period P3, the start signal VST may have a high level voltage. The first clock signal CLK1 may have a high level voltage. The second clock signal CLK2 may have a low level voltage. The voltage of the first node N1 may have a high level voltage. The voltage of the control node CTRL may have a high level voltage. The voltage of the fifth node N5 may have a low level voltage. The gate signal OUT may have a high level voltage.

During the fourth driving period P4, the start signal VST may have a low level voltage. The first clock signal CLK1 may have a low level voltage. The second clock signal CLK2 may have a high level voltage. The voltage of the first node N1 may have a high level voltage. The voltage of the control node CTRL may have a high level voltage. The voltage of the fifth node N5 may have a low level voltage. The gate signal OUT may have a high level voltage.

During the fifth driving period P5, the start signal VST may have a low level voltage. The first clock signal CLK1 may have a high level voltage. The second clock signal CLK2 may have a low level voltage. The voltage of the first node N1 may have a low level voltage. The voltage of the control node CTRL may have a low level voltage. The voltage of the fifth node N5 may have a high level voltage. The gate signal OUT may have a low level voltage.

Hereinafter, the emission control driver EMD for each driving period according to the voltage level of the signals is described.

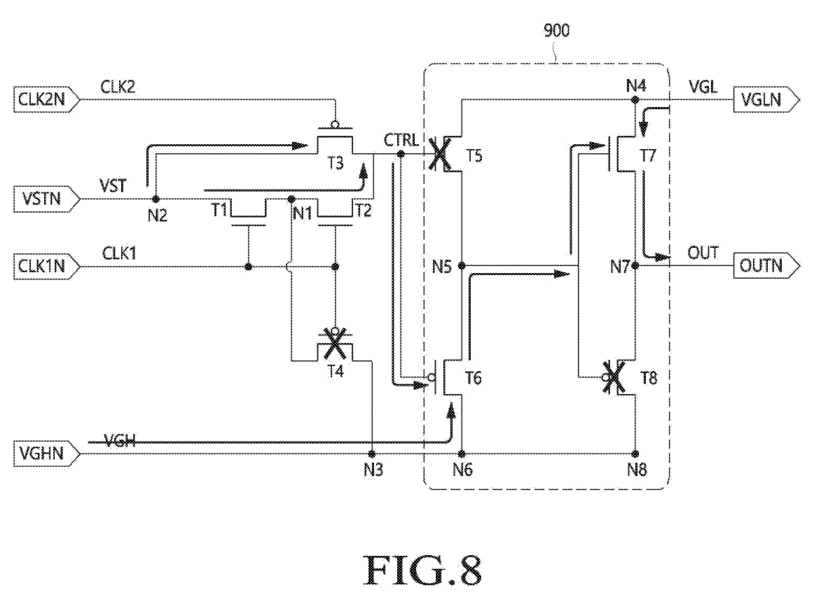

FIG. 8 is a view illustrating a first driving period P1 of an emission control driver EMD according to one or more embodiments of the present disclosure.

Referring to FIG. 8, as the first clock signal CLK1 has the high level voltage, the first transistor T1 and the second transistor T2 may be turned on. As the first transistor T1 and the second transistor T2 are turned on, a start signal VST having a low level voltage may be input to the control node CTRL.

As the first clock signal CLK1 has the high level voltage, the fourth transistor T4 may be turned off. As the fourth transistor T4 is turned off, the high level gate voltage VGH may not be input to the first node N1.

As the second clock signal CLK2 has the low level voltage, the third transistor T3 may be turned on. As the third transistor T3 is turned on, a start signal VST having a low level voltage may be input to the control node CTRL.

As the voltage of the control node CTRL is the low level voltage, the fifth transistor T5 may be turned off. Accordingly, the low level gate voltage VGL may not be input to the fifth node N5.

As the voltage of the control node CTRL is the low level voltage, the sixth transistor T6 may be turned on. Accordingly, the high level gate voltage VGH may be input to the fifth node N5.

As the high level gate voltage VGH is input to the fifth node N5, the seventh transistor T7 may be turned on. As the seventh transistor T7 is turned on, the low level gate voltage VGL may be input to the seventh node N7. Accordingly, the gate signal OUT having the low level gate voltage VGL may be output to the output node OUTN and output to the plurality of subpixels SP in the display area DA.

As the high level gate voltage VGH is input to the fifth node N5, the eighth transistor T8 may be turned off. As the eighth transistor T8 is turned off, the high level gate voltage VGH may not be input to the seventh node N7.

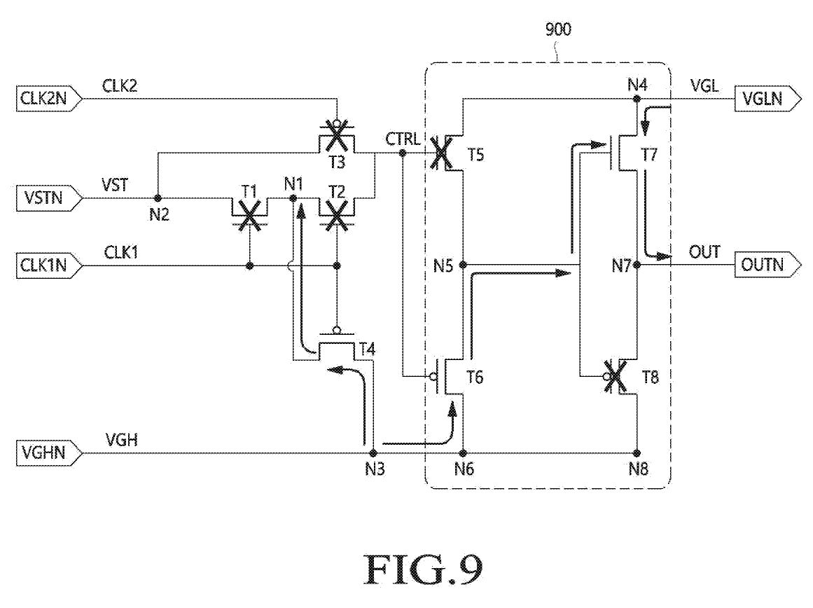

FIG. 9 is a view illustrating a second driving period P2 of an emission control driver EMD according to one or more embodiments of the present disclosure.

Referring to FIG. 9, as the first clock signal CLK1 has the low level voltage, the first transistor T1 and the second transistor T2 may be turned off. As the first transistor T1 and the second transistor T2 are turned off, the start signal VST may not be input to the control node CTRL.

As the first clock signal CLK1 has the low level voltage, the fourth transistor T4 may be turned on. As the fourth transistor T4 is turned on, a high level gate voltage VGH may be input to the first node N1.

As the second clock signal CLK2 has the high level voltage, the third transistor T3 may be turned off. As the third transistor T3 is turned off, a start signal VST having a high level voltage may not be input to the control node CTRL.

As the start signal VST having a high level voltage is not input to the control node CTRL, the voltage of the control node CTRL may be maintained as a low level voltage.

As the voltage of the control node CTRL is the low level voltage, the fifth transistor T5 may be turned off. Accordingly, the low level gate voltage VGL may not be input to the fifth node N5.

As the voltage of the control node CTRL is the low level voltage, the sixth transistor T6 may be turned on. Accordingly, the high level gate voltage VGH may be input to the fifth node N5.

As the high level gate voltage VGH is input to the fifth node N5, the seventh transistor T7 may be turned on. As the seventh transistor T7 is turned on, the low level gate voltage VGL may be input to the seventh node N7. Accordingly, the gate signal OUT having the low level gate voltage VGL may be output to the output node OUTN and output to the plurality of subpixels SP in the display area DA.

As the high level gate voltage VGH is input to the fifth node N5, the eighth transistor T8 may be turned off. As the eighth transistor T8 is turned off, the high level gate voltage VGH may not be input to the seventh node N7.

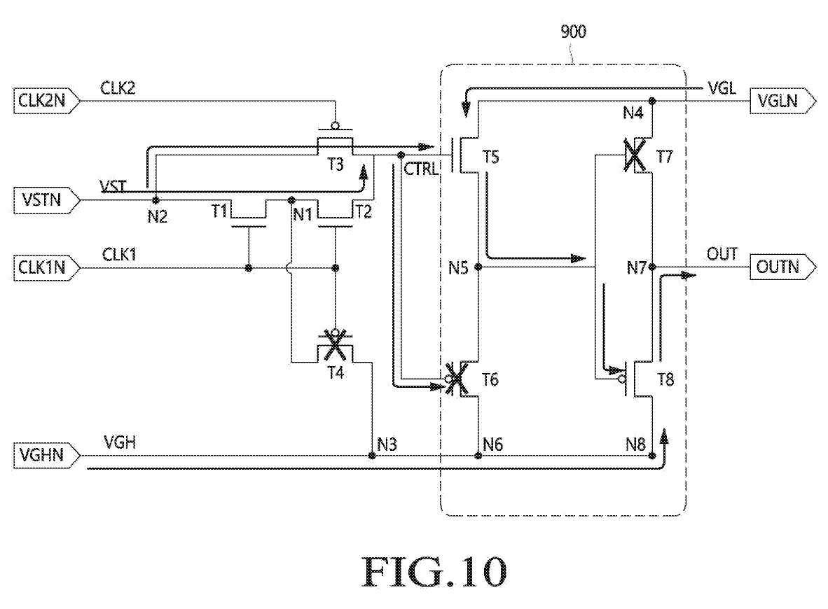

FIG. 10 is a view illustrating a third driving period P3 of an emission control driver EMD according to one or more embodiments of the present disclosure.

Referring to FIG. 10, as the first clock signal CLK1 has the high level voltage, the first transistor T1 and the second transistor T2 may be turned on. As the first transistor T1 and the second transistor T2 are turned on, a start signal VST having a high level voltage may be input to the control node CTRL.

As the first clock signal CLK1 has the high level voltage, the fourth transistor T4 may be turned off. As the fourth transistor T4 is turned off, the high level gate voltage VGH may not be input to the first node N1.

As the second clock signal CLK2 has the low level voltage, the third transistor T3 may be turned on. As the third transistor T3 is turned on, a start signal VST having a low level voltage may be input to the control node CTRL.

As the voltage of the control node CTRL is the high level voltage, the fifth transistor T5 may be turned on. Accordingly, the low level gate voltage VGL may be input to the fifth node N5.

As the voltage of the control node CTRL is the high level voltage, the sixth transistor T6 may be turned off. Accordingly, the high level gate voltage VGH may not be input to the fifth node N5.

As the low level gate voltage VGL is input to the fifth node N5, the seventh transistor T7 may be turned off. As the seventh transistor T7 is turned off, the low level gate voltage VGL may not be input to the seventh node N7.

As the low level gate voltage VGL is input to the fifth node N5, the eighth transistor T8 may be turned on. As the eighth transistor T8 is turned on, the high level gate voltage VGH may be input to the seventh node N7. Accordingly, the gate signal OUT having the high level gate voltage VGH may be output to the output node OUTN and output to the plurality of subpixels SP in the display area DA.

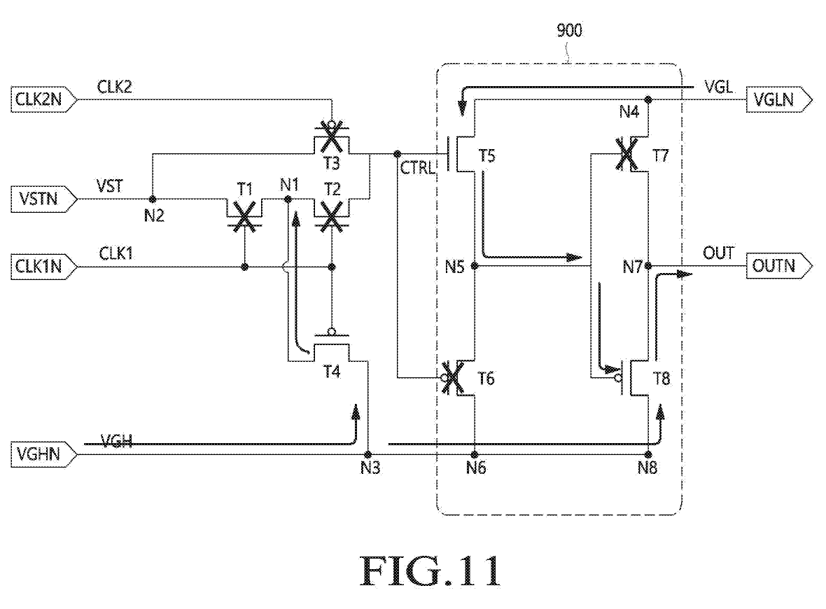

FIG. 11 is a view illustrating a fourth driving period P4 of an emission control driver EMD according to one or more embodiments of the present disclosure.

Referring to FIG. 11, as the first clock signal CLK1 has the low level voltage, the first transistor T1 and the second transistor T2 may be turned off. As the first transistor T1 and the second transistor T2 are turned off, the start signal VST may not be input to the control node CTRL.

As the first clock signal CLK1 has the low level voltage, the fourth transistor T4 may be turned on. As the fourth transistor T4 is turned on, a high level gate voltage VGH may be input to the first node N1. As the high level gate voltage VGH is input to the first node N1, the difference between the voltage of the first clock signal CLK1 and the voltage of the first node N1 may be lower than the threshold voltage of the second transistor T2.

As the second clock signal CLK2 has the high level voltage, the third transistor T3 may be turned off. As the third transistor T3 is turned off, a start signal VST having a low level voltage may not be input to the control node CTRL.

While the start signal VST is not input to the control node CTRL, the control node CTRL may maintain the high level voltage according to the short period during which the fourth driving period P4 may maintain the voltage.

When the second transistor T2 is an oxide semiconductor transistor, the threshold voltage of the second transistor T2 may decrease. As the threshold voltage decreases, the second transistor T2 may be turned on. Accordingly, an unintended current flow may occur from the control node CTRL to the first node N1. Even when the threshold voltage of the second transistor T2 is lowered, as the high level gate voltage VGH is input to the first node N1, an unintended current flow from the control node CTRL to the first node N1 may not occur.

As the voltage of the control node CTRL is the high level voltage, the fifth transistor T5 may be turned on. Accordingly, the low level gate voltage VGL may be input to the fifth node N5.

As the voltage of the control node CTRL is the high level voltage, the sixth transistor T6 may be turned off. Accordingly, the high level gate voltage VGH may not be input to the fifth node N5.

As the low level gate voltage VGL is input to the fifth node N5, the seventh transistor T7 may be turned off. As the seventh transistor T7 is turned off, the low level gate voltage VGL may not be input to the seventh node N7.

As the low level gate voltage VGL is input to the fifth node N5, the eighth transistor T8 may be turned on. As the eighth transistor T8 is turned on, the high level gate voltage VGH may be input to the seventh node N7. Accordingly, the gate signal OUT having the high level gate voltage VGH may be output to the output node OUTN and output to the plurality of subpixels SP in the display area DA.

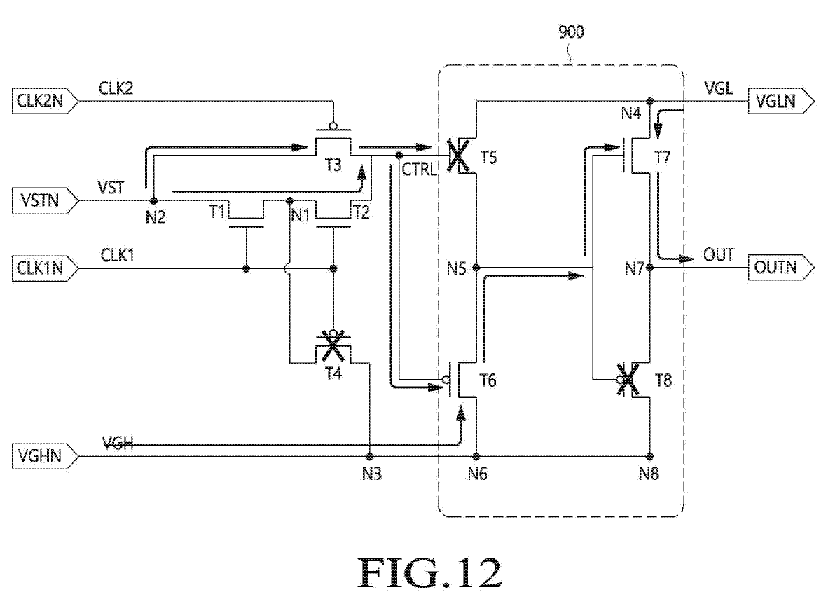

FIG. 12 is a view illustrating a fifth driving period P5 of an emission control driver EMD according to one or more embodiments of the present disclosure.

Referring to FIG. 12, as the first clock signal CLK1 has the high level voltage, the first transistor T1 and the second transistor T2 may be turned on. As the first transistor T1 and the second transistor T2 are turned on, a start signal VST having a low level voltage may be input to the control node CTRL.

As the first clock signal CLK1 has the high level voltage, the fourth transistor T4 may be turned off. As the fourth transistor T4 is turned off, the high level gate voltage VGH may not be input to the first node N1.

As the second clock signal CLK2 has the low level voltage, the third transistor T3 may be turned on. As the third transistor T3 is turned on, a start signal VST having a low level voltage may be input to the control node CTRL.

As the voltage of the control node CTRL is the low level voltage, the fifth transistor T5 may be turned off. Accordingly, the low level gate voltage VGL may not be input to the fifth node N5.

As the voltage of the control node CTRL is the low level voltage, the sixth transistor T6 may be turned on. Accordingly, the high level gate voltage VGH may be input to the fifth node N5.

As the high level gate voltage VGH is input to the fifth node N5, the seventh transistor T7 may be turned on. As the seventh transistor T7 is turned on, the low level gate voltage VGL may be input to the seventh node N7. Accordingly, the gate signal OUT having the low level gate voltage VGL may be output to the output node OUTN and output to the plurality of subpixels SP in the display area DA.

As the high level gate voltage VGH is input to the fifth node N5, the eighth transistor T8 may be turned off. As the eighth transistor T8 is turned off, the high level gate voltage VGH may not be input to the seventh node N7.

A display device according to one or more embodiments of the present disclosure may be described as follows.

A display device may comprise a display area where an image may be displayed, a non-display area outside of the display area, and a gate driving circuit outputting a gate signal to the display area.

The gate driving circuit may include a first transistor configured to control a connection between a first node and a second node to which a start signal is input according to a first clock signal input to a first gate node, a second transistor configured to control a connection between the first node and a control node according to the first clock signal input to a second gate node, a third transistor configured to control a connection between the second node and the control node according to a second clock signal input to a third gate node, a fourth transistor configured to control a connection between the first node and a third node to which a high level gate voltage is input according to the first clock signal input to a fourth gate node, and an output circuit configured to output the gate signal to the display area according to a voltage level of the control node.

While the high level gate voltage is input to the first node according to a voltage of the first clock signal, a difference between the voltage of the first clock signal and a voltage of the first node may be lower than a threshold voltage of the second transistor.

While the first clock signal has a high level voltage, the first transistor and the second transistor may be turned on, and the fourth transistor may be turned off.

As the first transistor and the second transistor are turned on, the start signal may be input to the control node.

As the fourth transistor is turned off, the high level gate voltage may not be input to the first node.

The first clock signal and the second clock signal may have opposite phases.

While the second clock signal has a low level signal, the third transistor may be turned on and, while the second clock signal has a high level signal, the third transistor may be turned off.

While the control node has a high level voltage, the gate signal having the high level gate voltage may be output to the display area.

While the control node has a low level voltage, the gate signal having a low level gate voltage may be output to the display area.

The output circuit may include a fifth transistor configured to control a connection between a fourth node to which a low level gate voltage is input and a fifth node according to a voltage input to the control node, a sixth transistor configured to control a connection between a sixth node to which the high level gate voltage is input and the fifth node according to the voltage applied to the control node, a seventh transistor configured to control a connection between the fourth node and a seventh node connected to an output node outputting the gate signal to the display area according to a voltage applied to the fifth node, and an eighth transistor configured to control a connection between the seventh node and an eighth node to which the high level gate voltage is input according to the voltage applied to the fifth node.

The first transistor, the second transistor, the fifth transistor, and the seventh transistor may be oxide semiconductor transistors.

The third transistor, the fourth transistor, the sixth transistor, and the eighth transistor may be low-temperature polycrystalline silicon (LTPS) transistors.

While the control node has a high level voltage, the fifth transistor may be turned on, and the sixth transistor may be turned off.

While the fifth transistor may be turned on, the fifth node may receive the low level gate voltage.

While the fifth node receives the low level gate voltage, the seventh transistor may be turned off, and the eighth transistor may be turned on.

While the eighth transistor is turned on, the gate signal having the high level gate voltage may be output to the display area.

While the control node has a low level voltage, the fifth transistor may be turned off, and the sixth transistor may be turned on.

While the sixth transistor may be turned on, the fifth node may receive the high level gate voltage.

While the fifth node receives the high level gate voltage, the seventh transistor may be turned on, and the eighth transistor may be turned off.

While the seventh transistor is turned on, the gate signal having the low level gate voltage may be output to the display area.

While the start signal has a low level voltage, and the start signal is not input to the control node, a voltage of the control node may be maintained.

The gate driving circuit includes a first driving period, a second driving period and a third driving period, during the first driving period, the start signal has a low level voltage, the first clock signal has a high level voltage, the second clock signal has a low level voltage, a voltage of the first node has a low level voltage, and a voltage of the control node has a low level voltage; during the second driving period, the start signal has a high level voltage, the first clock signal has a low level voltage, the second clock signal has a high level voltage, the voltage of the first node has a high level voltage, and the voltage of the control node has a low level voltage; and during the third driving period, the start signal has a high level voltage, the first clock signal has a high level voltage, the second clock signal has a low level voltage, the voltage of the first node has a high level voltage, and the voltage of the control node has a high level voltage.

The gate driving circuit further includes a fourth driving period and a fifth driving period, during the fourth driving period, the start signal has a low level voltage, the first clock signal has a low level voltage, the second clock signal has a high level voltage, the voltage of the first node has a high level voltage, and the voltage of the control node has a high level voltage; and during the fifth driving period, the start signal has a low level voltage, the first clock signal has a high level voltage, the second clock signal has a low level voltage, the voltage of the first node has a low level voltage, and the voltage of the control node has a low level voltage.

When the first clock signal has the high level voltage, the first transistor and the second transistor are turned on, and the fourth transistor is turned off, and wherein when the second clock signal has the low level voltage, the third transistor is turned on.

The gate driving circuit may include a first transistor configured to control a connection between a first node and a second node to which a start signal is input according to a first clock signal input to a first gate node, a second transistor configured to control a connection between the first node and a control node according to the first clock signal input to a second gate node, a third transistor configured to control a connection between the second node and the control node according to a second clock signal input to a third gate node, a fourth transistor configured to control a connection between the first node and a third node to which a high level gate voltage is input according to the first clock signal input to a fourth gate node, and an output circuit configured to output the gate signal to an output node according to a voltage level of the control node.

While the high level gate voltage is input to the first node according to a voltage of the first clock signal, a difference between the voltage of the first clock signal and a voltage of the first node may be lower than a threshold voltage of the second transistor.

While the first clock signal has a high level voltage, the first transistor and the second transistor may be turned on, and the fourth transistor may be turned off.

As the first transistor and the second transistor are turned on, the start signal may be input to the control node.

As the fourth transistor is turned off, the high level gate voltage may not be input to the first node.

The first clock signal and the second clock signal may have opposite phases.

While the second clock signal has a low level signal, the third transistor may be turned on and, while the second clock signal has a high level signal, the third transistor may be turned off.

While the control node has a high level voltage, the gate signal having the high level gate voltage may be output to the output node.

While the control node has a low level voltage, the gate signal having a low level gate voltage may be output to the output node.

The output circuit may include a fifth transistor configured to control a connection between a fourth node to which a low level gate voltage is input and a fifth node according to a voltage input to the control node, a sixth transistor configured to control a connection between a sixth node to which the high level gate voltage is input and the fifth node according to the voltage applied to the control node, a seventh transistor configured to control a connection between the fourth node and a seventh node connected to an output node according to a voltage applied to the fifth node, and an eighth transistor configured to control a connection between the seventh node and an eighth node to which the high level gate voltage is input according to the voltage applied to the fifth node.

The first transistor, the second transistor, the fifth transistor, and the seventh transistor may be oxide semiconductor transistors.

The third transistor, the fourth transistor, the sixth transistor, and the eighth transistor may be low-temperature polycrystalline silicon (LTPS) transistors.

While the control node has a high level voltage, the fifth transistor may be turned on, and the sixth transistor may be turned off.

While the fifth transistor may be turned on, the fifth node may receive the low level gate voltage.

While the fifth node receives the low level gate voltage, the seventh transistor may be turned off, and the eighth transistor may be turned on.

While the eighth transistor is turned on, the gate signal having the high level gate voltage may be output to the output node.

While the control node has a low level voltage, the fifth transistor may be turned off, and the sixth transistor may be turned on.

While the sixth transistor may be turned on, the fifth node may receive the high level gate voltage.

While the fifth node receives the high level gate voltage, the seventh transistor may be turned on, and the eighth transistor may be turned off.

While the seventh transistor is turned on, the gate signal having the low level gate voltage may be output to the output node.

While the start signal has a low level voltage, and the start signal is not input to the control node, a voltage of the control node may be maintained.

A display device may include a plurality of subpixels, each subpixel comprising: a driving transistor having a first electrode, a second electrode and a gate electrode; a first scan transistor that is controlled by a first scan signal and is electrically connected between the first electrode and the gate electrode of the driving transistor; a second scan transistor that is controlled by a second scan signal and is electrically connected to a data line, and the second electrode of the driving transistor; a first emission control transistor that is controlled by a first emission control signal and is electrically connected between a driving voltage line and the first electrode of the driving transistor; a second emission control transistor that is controlled by a second emission control signal, and is electrically connected between the second electrode of the driving transistor and a anode electrode of a light emitting element; a third emission control transistor that is controlled by the second emission control signal, and is connected between an initialization voltage line and the anode electrode of the light emitting element; and a capacitor that is electrically connected between the gate electrode of the driving transistor and the anode electrode of the light emitting element.

The driving transistor, the first scan transistor, and the third emission control transistor are oxide semiconductor transistors, and wherein the first emission control transistor, the second scan transistor, and the second emission control transistor are low-temperature polycrystalline silicon LTPS transistors.

The above description has been presented to enable any person skilled in the art to make and use the technical idea of the present disclosure, and has been provided in the context of a particular application and its requirements. Various modifications, additions and substitutions to the described exemplary embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A gate driving circuit, comprising:
a first transistor configured to control a connection between a first node and a second node, wherein a start signal is input to the second node according to a first clock signal input to a first gate node of the first transistor;
a second transistor configured to control a connection between the first node and a control node according to the first clock signal input to a second gate node of the second transistor;
a third transistor configured to control a connection between the second node and the control node according to a second clock signal input to a third gate node of the third transistor;
a fourth transistor configured to control a connection between the first node and a third node to which a high level gate voltage is input according to the first clock signal input to a fourth gate node of the fourth transistor; and
an output circuit configured to output a gate signal to an output node according to a voltage level of the control node.

2. The gate driving circuit of claim 1, wherein while the high level gate voltage is input to the first node according to a voltage of the first clock signal, a difference between the voltage of the first clock signal and a voltage of the first node is lower than a threshold voltage of the second transistor.

3. The gate driving circuit of claim 1, wherein while the first clock signal has a high level voltage, the first transistor and the second transistor are turned on, and the fourth transistor is turned off,
wherein as the first transistor and the second transistor are turned on, the start signal is input to the control node, and
wherein as the fourth transistor is turned off, the high level gate voltage is not input to the first node.

4. The gate driving circuit of claim 3, wherein the first clock signal and the second clock signal have opposite phases, and
wherein while the second clock signal has a low level signal, the third transistor is turned on and, while the second clock signal has a high level signal, the third transistor is turned off.

5. The gate driving circuit of claim 1, wherein while the control node has a high level voltage, the gate signal having the high level gate voltage is output to an output node, and
wherein while the control node has a low level voltage, the gate signal having a low level gate voltage is output to the output node.

6. The gate driving circuit of claim 1, wherein the output circuit includes:
a fifth transistor configured to control a connection between a fourth node to which a low level gate voltage is input and a fifth node according to a voltage applied to the control node;
a sixth transistor configured to control a connection between a sixth node to which the high level gate voltage is input and the fifth node according to the voltage applied to the control node;
a seventh transistor configured to control a connection between the fourth node and a seventh node connected to an output node according to a voltage applied to the fifth node; and
an eighth transistor configured to control a connection between the seventh node and an eighth node to which the high level gate voltage is input according to the voltage applied to the fifth node.

7. The gate driving circuit of claim 6, wherein the first transistor, the second transistor, the fifth transistor, and the seventh transistor are oxide semiconductor transistors, and
wherein the third transistor, the fourth transistor, the sixth transistor, and the eighth transistor are low-temperature polycrystalline silicon (LTPS) transistors.

8. The gate driving circuit of claim 7, wherein while the control node has a high level voltage, the fifth transistor is turned on, and the sixth transistor is turned off,
wherein while the fifth transistor is turned on, the fifth node receives the low level gate voltage,
wherein while the fifth node receives the low level gate voltage, the seventh transistor is turned off and the eighth transistor is turned on, and
wherein while the eighth transistor is turned on, the gate signal having the high level gate voltage is output to the output node.

9. The gate driving circuit of claim 7, wherein while the control node has a low level voltage, the fifth transistor is turned off, and the sixth transistor is turned on,
wherein while the sixth transistor is turned on, the fifth node receives the high level gate voltage,
wherein while the fifth node receives the high level gate voltage, the seventh transistor is turned on and the eighth transistor is turned off, and
wherein while the seventh transistor is turned on, the gate signal having the low level gate voltage is output to the output node.

10. The gate driving circuit of claim 1, wherein while the start signal has a low level voltage and the start signal is not input to the control node, a voltage of the control node is maintained.

11. The gate driving circuit of claim 1, wherein a plurality of driving periods of the gate driving circuit include a first driving period, a second driving period and a third driving period,
wherein during the first driving period, the start signal has a low level voltage, the first clock signal has a high level voltage, the second clock signal has a low level voltage, a voltage of the first node has a low level voltage, and a voltage of the control node has a low level voltage,
wherein during the second driving period, the start signal has a high level voltage, the first clock signal has a low level voltage, the second clock signal has a high level voltage, the voltage of the first node has a high level voltage, and the voltage of the control node has a low level voltage, and
wherein during the third driving period, the start signal has a high level voltage, the first clock signal has a high level voltage, the second clock signal has a low level voltage, the voltage of the first node has a high level voltage, and the voltage of the control node has a high level voltage.

12. The gate driving circuit of claim 11, wherein the plurality of driving periods of the gate driving circuit further include a fourth driving period and a fifth driving period,
wherein during the fourth driving period, the start signal has a low level voltage, the first clock signal has a low level voltage, the second clock signal has a high level voltage, the voltage of the first node has a high level voltage, and the voltage of the control node has a high level voltage, and
wherein during the fifth driving period, the start signal has a low level voltage, the first clock signal has a high level voltage, the second clock signal has a low level voltage, the voltage of the first node has a low level voltage, and the voltage of the control node has a low level voltage.

13. The gate driving circuit of claim 11, wherein when the first clock signal has the high level voltage, the first transistor and the second transistor are turned on and the fourth transistor is turned off, and
wherein when the second clock signal has the low level voltage, the third transistor is turned on.

14. A display device, comprising:
a display area where an image is displayed;
a non-display area outside of the display area; and
the gate driving circuit of claim 1, wherein the gate driving circuit is configured to output the gate signal to the display area.
